(19) United States
(12) Patent Application Publication
(10) Pub. No.: US 2008/0316063 A1
(43) Pub. Date: Dec. 25, 2008

(54) Integrated Keyboard With Personal Computer

(76) Inventor: Farzin Yassini, Stockton, CA (US)

Correspondence Address: Ashok Tankha, 36 Greenleigh Drive, Sewell, NJ, 08080, US

(21) Appl. No.: 12/142,795

(22) Filed: Jun. 20, 2008

Related U.S. Application Data
(60) Provisional application No. 60/945,346, filed on Jun. 21, 2007.

(51) Int. Cl. H03K 17/94

(52) U.S. Cl. 341/22

(57) ABSTRACT

Disclosed herein is an eco friendly board top computing device that is integrated with computer components, has an ergonomic shape, provides recharge of a pointing device, consumes less energy, and is eco friendly. The board top computing device comprises a first section, a second section, and a third section. The first section comprises an alphanumeric keypad. A recharging cradle is provisioned on the first section for recharging a wireless pointing device. The second section comprises a motherboard comprising multiple computer components, a receiver for the wireless pointing device, an internal modem, an optical disc drive, and a power supply connector. The second section further comprises universal serial bus ports for attaching external peripheral devices and a wireless local area network card for transmitting and receiving data over a computer network. The third section comprises a hard drive for storing data and multiple fans for dissipating heat.

### CROSS REFERENCE TO RELATED APPLICATIONS

This application claims the benefit of the provisional patent application 60/945,346 titled “The integrated keyboard with personal computer”, filed on Jun. 21, 2007 in the United States Patent and Trademark Office.

### BACKGROUND

This invention, in general, relates to computing devices. More particularly, this invention relates to an integrated computer within a keyboard.

Typical desktop computers comprise components, for example, a visual display unit, a keyboard, and a computer case with a main board, a central processing unit, a hard disk, and a memory. The components of these desktop computers are typically provided separately, thereby causing spatial restrictions, complicated electric connections, and limited mobility. The complicated electric connections result in a disorganized appearance. Moreover, typical keyboards create health problems associated with repeated motions of the wrists and fingers of the user. Furthermore, typical desktop computers consume high energy. Laptops do not require as much space as the desktop computer and are very mobile. The complicated electric connections are also not present in the laptops. However, the visual display unit of the laptop is at a very small distance from the keyboard thereby posing health problems, etc. Moreover, the touchpad of the laptop which is used as a pointing device interferes while a user operates the keyboard.

Often a wireless mouse may be used as a pointing device. The wireless mouse requires recharging after a period of time. The user therefore needs to replace the battery or put the wireless mouse on a cradle of a recharging unit in order to recharge the wireless mouse. Requiring the wireless mouse to be recharged when the user is in the process of computing may be frustrating to the user. Therefore, there is need for recharging the wireless mouse on a single computing device for user convenience.

Hence, there is a need for a user friendly board top computing device that is integrated with computer components, has an ergonomic shape, provides recharge of a pointing device, consumes less energy, and is eco friendly. There is also a need for the board top computing device that occupies less space and provides mobility.

### SUMMARY OF THE INVENTION

This summary is provided to introduce a selection of concepts in a simplified form that are further described in the detailed description of the invention. This summary is not intended to identify key or essential inventive concepts of the claimed subject matter, nor is it intended for determining the scope of the claimed subject matter.

The board top computing device disclosed herein addresses the above mentioned need for a user friendly computing device that is integrated with computer components, has an ergonomic shape, provides recharge of a pointing device, consumes less energy, and is eco friendly. The board top computing device disclosed herein also occupies less space, provides mobility, and performs data processing functions.

The board top computing device disclosed herein comprises a first section, a second section, and a third section. The first section comprises an alphanumeric keypad. A recharging cradle is provisioned on the first section for recharging a wireless pointing device. The second section of the board top computing device is in communication with and below the first section. The second section comprises a motherboard comprising multiple computer components. The computer components comprise a primary memory, a central processing unit, a clock generator, peripheral device controllers, and an adaptable connector for connecting to a visual display unit. The second section further comprises a receiver for the wireless pointing device, an internal modem, an optical disc drive, and a power supply connector. The board top computing device connects to an external power supply. The second section further comprises terminals and universal serial bus ports for connecting to external peripheral devices. The second section further comprises a wireless local area network card built into the motherboard for transmitting and receiving data over a computer network.

The third section of the board top computing device comprises a hard drive for storing data and multiple fans for dissipating heat generated by the second section. The third section may also comprise a personal computer card slot.

### BRIEF DESCRIPTION OF THE DRAWINGS

The foregoing summary, as well as the following detailed description of the invention, is better understood when read in conjunction with the appended drawings. For the purpose of illustrating the invention, exemplary constructions of the invention are shown in the drawings. However, the invention is not limited to the specific methods and instrumentalities disclosed herein.

FIG. 1 illustrates a board top computing device.

FIG. 2 exemplarily illustrates an exploded view of the board top computing device.

FIG. 3 exemplarily illustrates the board top computing device along with a visual display unit.

### DETAILED DESCRIPTION OF THE INVENTION

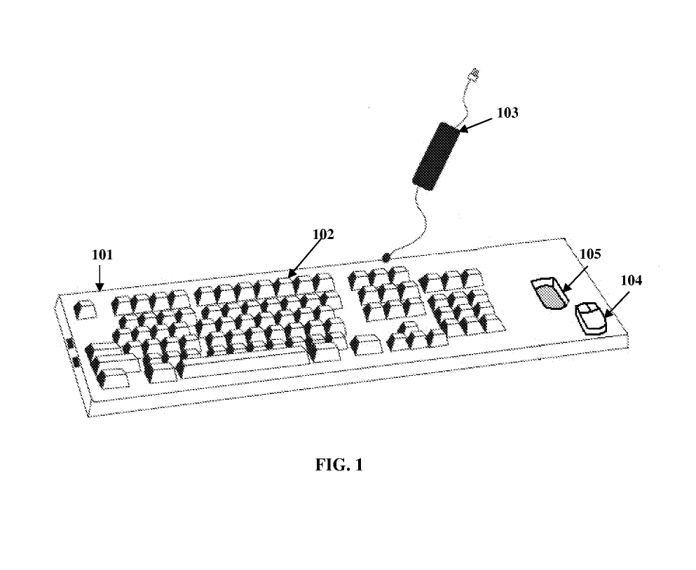

FIG. 1 illustrates a board top computing device 101. The board top computing device 101 is an integrated keyboard with a personal computer. The board top computing device 101 is designed with ergonomic considerations to minimize muscle strain and related problems. For example, the board top computing device 101 may be designed with a key pad comprising keys separated into two or three groups. This separation allows a user to type at a different angle to reduce muscle strain. The board top computing device 101 may include elevated sections at different angles. The board top computing device 101 may be designed to have a thickness of about 1.5″ or less.

The board top computing device 101 may also be designed for users with carpal tunnel syndrome (CTS) or median neuropathy. CTS is a medical condition at the wrist, in which the median nerve is compressed at the wrist, leading to pain and muscle weakness in the forearm and hand. Typing on a computer keyboard or a typewriter has been identified as contributing to repetitive stress induced CTS.

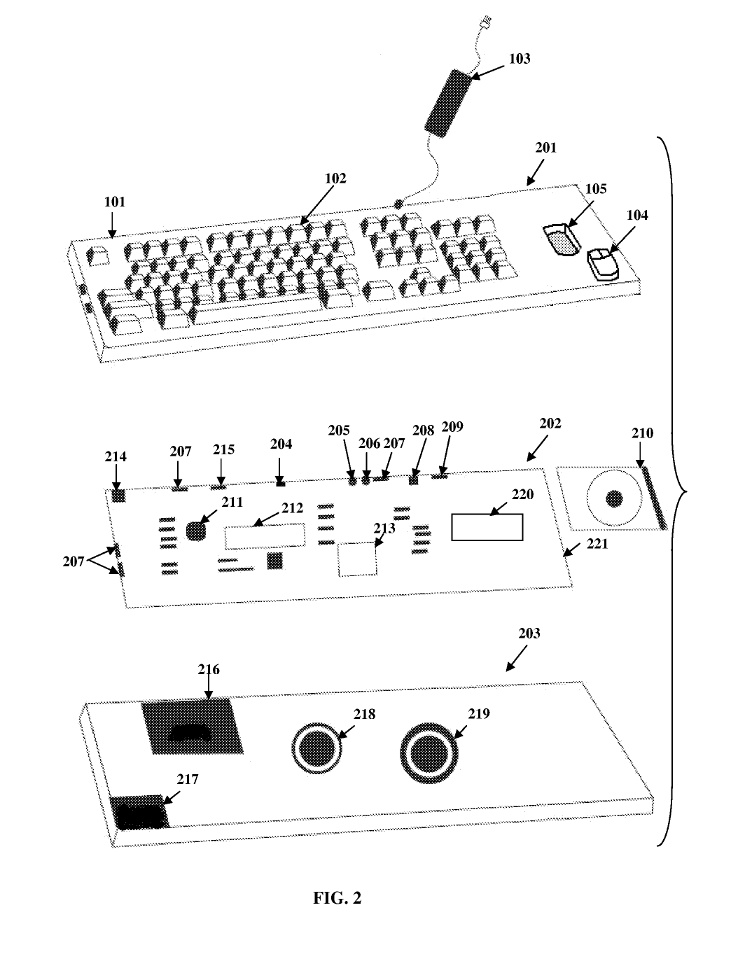

FIG. 2 exemplarily illustrates an exploded view of the board top computing device 101. The board top computing device 101 comprises a first section 201, a second section 202, and third section 203. The first section 201 comprises an alphanumeric keypad 102. The alphanumeric keypad 102 comprises alphanumeric keys, for example, alphabetic symbols, numerals 0 to 9, punctuation keys, control keys, function keys, etc. The board top computing device 101 comprises a recharging cradle 105 provisioned on the first section 201 for recharging a wireless pointing device 104. The wireless pointing device 104 may be a wireless mouse, a stylus, etc. The recharging cradle 105 is a slot where the wireless pointing device 104 is placed for the recharging. The wireless pointing device 104 may also be recharged internally. The recharging cradle 105 provisioned on the first section 201 may be positioned horizontally or vertically for recharging the wireless pointing device 104.The recharging cradle 105 may comprise internal circuitry for recharging the wireless pointing device 104. The wireless pointing device 104 is used as a pointing device for interacting with a visual display unit 301. The wireless pointing device 104 does not interfere with the alphanumeric keypad 102 operation. The wireless pointing device 104 may be a radio frequency wireless pointing device in conjunction with a radio frequency receiver integrated within the board top computing device 101.

The second section 202 is in communication with and below the first section 201 of the board top computing device 101. The second section 202 comprises a motherboard 221, a receiver 204, an internal modem, an optical disc drive 210, and a power supply connector 209. The motherboard 221 is a printed circuit board that provides connection points for multiple computer components and external peripheral devices. The basic circuitry and computer components required for a computer to function are onboard the motherboard 221 or are connected with a cable. The motherboard 221 allows parts of a computer to receive power and communicate with each other. The computer components comprise a primary memory 212, a central processing unit (CPU) 213, a clock generator, peripheral device controllers, and an adaptable connector 215 for connecting to the visual display unit 301. The primary memory 212 is a main memory that is a storage area utilized by the CPU 213. The CPU 213 is a microprocessor used for performing the processing of data received from other hardware computer components and software programs running on the computer. The CPU 213, for example, an Intel® Atom processor may be used. The Intel® Atom processor consumes less energy thereby enabling the board top computing device 101 to be eco friendly. The motherboard 221 may further comprise a registered jack 45 214 and a registered jack 11 208.

The clock generator supplies timing signals to synchronize multiple processors and chipsets on the motherboard 221. The peripheral device controllers control transfer of the data between the board top computing device 101 and the peripheral devices. For example, the peripheral device controllers control transfer of the data between the board top computing device 101 and the visual display unit 301, printer, etc.

The receiver 204 for the wireless pointing device 104 may be a radio frequency receiver. The wireless pointing device 104 may use radio frequency technology to communicate information to the board top computing device 101. The receiver 204 receives signals, for example, radio frequency signals, from a transmitter in the wireless pointing device 104. The receiver 204 decodes the signals and transfers the signals to the board top computing device 101. The receiver 204 may be a built in component or a separate unit that plugs into a peripheral unit of the board top computing device 101. The adaptable connector 215 present on the motherboard 221 is used for connecting to the visual display unit 301. For example, the adaptable connector 215 used may be a video graphics array (VGA) connector. A VGA card present on the motherboard 221 may be designed to provide connection to multiple visual display units of different types and sizes.

The internal modem on the second section 202 is used for transmitting and receiving digital data over a communications line, for example, a telephone line or a cable line, and for converting the digital data to an analog signal. The optical disc drive 210 is used for reading and writing the data on optical discs. The optical discs may be compact discs, digital video discs, etc. The power supply connector 209 connects an external power supply 103 for supplying power to the board top computing device 101 and the visual display unit 301. The external power supply 103, for example, is similar to the external power supply used by a laptop. The external power supply 103 thereby consumes less power consumed by regular desktop computers. The external power supply 103 further supplies power to the recharging cradle 105. An internal power supply may also be used to supply power. The second section 202 may further comprise a personal system keyboard connector 205 and a personal system mouse connector 206 for connecting a keyboard and a mouse respectively. A connector 211 capable of supplying power to the visual display unit 301 is present on the motherboard 221.

The second section 202 of the board top computing device 101 further comprises terminals for connecting to the external peripheral devices, for example, printers, scanners, digital cameras, and audio devices. The second section 202 further comprises universal serial bus (USB) ports 207 for attaching the external peripheral devices. The second section 202 further comprises a wireless local area network card 220 built into the motherboard 221 for transmitting and receiving the data over a computer network. The wireless local area network card 220 provides access to wireless local area networks thereby eliminating traditional wired computer networks.

The third section 203 of the board top computing device 101 comprises a hard drive 216 for storing the data and multiple fans 218 and 219 for dissipating heat generated by the second section 202. The third section 203 comprises a CPU fan 219 for dissipating heat generated by the CPU 213. The third section 203 further comprises a VGA fan 218 for dissipating heat generated by the VGA connector. The hard drive 216 controls positioning, reading, and writing of a hard disc. The hard disc, packaged with the hard drive 216, furnishes the largest amount of non volatile data storage for the computer. The hard drive 216 may be of a smaller form factor, for example, 2.5″. The form factor is defined as physical size and shape of a device. The form factor, in respect to the hard drive 216, is defined as the diameter of the hard drive 216. The third section 203 of the board top computing device 101 comprises a personal computer card slot 217 for inserting a personal computer card. The personal computer card is a personal computer memory card international association (PCMCIA) card.

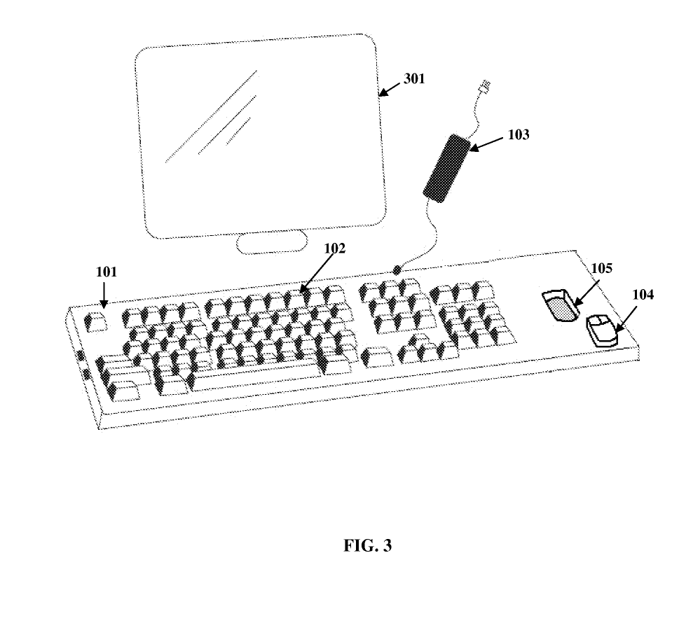

FIG. 3 exemplarily illustrates the board top computing device 101 along with the visual display unit 301. The visual display unit 301 may be of different types, for example, liquid crystal display (LCD) and cathode ray tube (CRT). The LCD is a thin and flat visual display unit 301 that is based on LCD technology. The LCD is lighter and saves more space. The LCD acquires power from the motherboard 221, thereby eliminating a long cable resulting in the board top computing device 101 being more eco friendly. The LCD is also lighter, thinner, and consumes lesser power. The CRT works on CRT technology and displays higher resolutions on a smaller visual display unit 301. The adaptable connector 215 sends display information to the visual display unit 301. The adaptable connector 215 connects the visual display unit 301 of different types and sizes.

The board top computing device 101 further comprises a battery for providing power backup in a case of power outage. The board top computing device 101 is capable of using any platform, for example, Microsoft Windows® and Macintosh®. The components in the first section 201, the second section 202, and the third section 203 are designed to be compact and of a smaller size. The board top computing device 101 is customizable and can be designed with different components and newer technologies to cater to the needs of multiple users, regions, businesses, etc.

It will be readily apparent that the various methods and algorithms described herein may be implemented in a computer readable medium appropriately programmed for general purpose computers and computing devices. Typically a processor, for e.g., one or more microprocessors will receive instructions from a memory or like device, and execute those instructions, thereby performing one or more processes defined by those instructions. Further, programs that implement such methods and algorithms may be stored and transmitted using a variety of media, for e.g., computer readable media in a number of manners. In one embodiment, hard-wired circuitry or custom hardware may be used in place of, or in combination with, software instructions for implementation of the processes of various embodiments. Thus, embodiments are not limited to any specific combination of hardware and software. A ‘processor’ means any one or more microprocessors, Central Processing Unit (CPU) devices, computing devices, microperipheral device controllers, digital signal processors or like devices. The term ‘computer-readable medium’ refers to any medium that participates in providing data, for example instructions that may be read by a computer, a processor or a like device. Such a medium may take many forms, including but not limited to, non-volatile media, volatile media, and transmission media. Non-volatile media include, for example, optical or magnetic disks and other persistent memory volatile media include Dynamic Random Access Memory (DRAM), which typically constitutes the main memory. Transmission media include coaxial cables, copper wire and fiber optics, including the wires that comprise a system bus coupled to the processor. Transmission media may include or convey acoustic waves, light waves and electromagnetic emissions, such as those generated during Radio Frequency (RF) and Infrared (IR) data communications. Common forms of computer-readable media include, for example, a floppy disk, a flexible disk, hard disk, magnetic tape, any other magnetic medium, a Compact Disc-Read Only Memory (CD-ROM), Digital Versatile Disc (DVD), any other optical medium, punch cards, paper tape, any other physical medium with patterns of holes, a Random Access Memory (RAM), a Programmable Read Only Memory (PROM), an Erasable Programmable Read Only Memory (EPROM), an Electrically Erasable Programmable Read Only Memory (EEPROM), a flash memory, any other memory chip or cartridge, a carrier wave as described hereinafter, or any other medium from which a computer can read. In general, the computer-readable programs may be implemented in any programming language. Some examples of languages that can be used include C, C++, C#, or JAVA. The software programs may be stored on or in one or more mediums as an object code. A computer program product comprising computer executable instructions embodied in a computer-readable medium comprises computer parsable codes for the implementation of the processes of various embodiments.

The present invention can be configured to work in a network environment including a computer that is in communication, via a communications network, with one or more devices. The computer may communicate with the devices directly or indirectly, via a wired or wireless medium such as the Internet, Local Area Network (LAN), Wide Area Network (WAN) or Ethernet, Token Ring, or via any appropriate communications means or combination of communications means. Each of the devices may comprise computers, such as those based on the Intel® processors, AMD® processors, UltraSPARC® processors, etc. that are adapted to communicate with the computer. Any number and type of machines may be in communication with the computer.

The foregoing examples have been provided merely for the purpose of explanation and are in no way to be construed as limiting of the present method and system disclosed herein. While the invention has been described with reference to various embodiments, it is understood that the words, which have been used herein, are words of description and illustration, rather than words of limitation. Further, although the invention has been described herein with reference to particular means, materials and embodiments, the invention is not intended to be limited to the particulars disclosed herein; rather, the invention extends to all functionally equivalent structures, methods and uses, such as are within the scope of the appended claims. Those skilled in the art, having the benefit of the teachings of this specification, may effect numerous modifications thereto and changes may be made without departing from the scope and spirit of the invention in its aspects.

I claim:

1. A board top computing device for performing data processing functions, comprising:
a first section comprising an alphanumeric keypad;
a recharging cradle provisioned on said first section for recharging a wireless pointing device;
a second section in communication with and below the first section, wherein said second section comprises:
a motherboard comprising a plurality of computer components, wherein said computer components comprise a primary memory, a central processing unit, a clock generator, peripheral device controllers, and an adaptable connector for connecting one or more visual display units;
a receiver for said wireless pointing device;
an optical disc drive for reading and writing data on optical discs;
a third section comprising:
a hard drive for storing data; and
a plurality of fans for dissipating heat generated by the second section;
whereby said board top computing device is eco friendly and performs said data processing functions.

2. The board top computing device of claim 1, wherein said second section further comprises a power supply connector for connecting an external power supply.

3. The board top computing device of claim 1, wherein said second section further comprises an internal modem for transmitting and receiving digital data over a communications line, wherein said internal modem converts said digital data to an analog signal.

4. The board top computing device of claim 1, wherein said adaptable connector is a video graphics array connector.

5. The board top computing device of claim 1, wherein said adaptable connector connects to said visual display units of one or more different types and sizes.

6. The board top computing device of claim 1, wherein said second section further comprises terminals for connecting to external peripheral devices, wherein said external peripheral devices comprise one or more of printers, scanners, digital cameras, and audio devices.

7. The board top computing device of claim 1, wherein said second section further comprises universal serial bus ports for attaching external peripheral devices.

8. The board top computing device of claim 1, wherein said second section further comprises a wireless local area network card built into said motherboard for transmitting and receiving data over a computer network.

9. The board top computing device of claim 1, further comprising a battery for providing power backup.

10. The board top computing device of claim 1, wherein said third section further comprises a personal computer card slot for inserting a personal computer card.
